(19) United States
(12) Patent Application Publication
(10) Pub. No.: US 2013/0101749 A1
(43) Pub. Date: Apr. 25, 2013

(54) Method and Apparatus for Enhanced Film Uniformity

(71) Applicants: Hong Sheng Yang, (US); Chi-I Lang, (US)

(72) Inventors: Hong Sheng Yang, (US); Chi-I Lang, (US)

(73) Assignee: INTERMOLECULAR, INC., San Jose, CA (US)

(21) Appl. No.: 13/281,299

(22) Filed: Oct. 25, 2011

(51) Int. Cl. C23C 14/35

(52) U.S. Cl. 427/523; 118/723 MP

(57) ABSTRACT

In one aspect of the invention, a process chamber is provided. The process chamber includes a plurality of sputter guns with a target and a main magnet affixed to one end of each of the sputter guns. A substrate support is disposed at a distance from the plurality of sputter guns. An auxiliary magnet is disposed near the substrate. The auxiliary magnet surrounds an outer peripheral surface of the substrate support. In alternative embodiments the magnet may be disposed in a plate or holder disposed below or above the substrate support. In additional embodiments, the auxiliary magnet may be embedded within the substrate support. Furthermore, the auxiliary magnet can either be permanent magnets or electromagnets. A method of performing a deposition process is also included.

### TECHNICAL FIELD

The present disclosure generally relates to the field of thin film deposition apparatus and method and more particularly to sputter deposition apparatus and methods.

### BACKGROUND

Physical vapor deposition (PVD) is commonly used within the semiconductor industry, as well as within solar, glass coating, and other industries, in order to deposit a layer over a substrate. Sputtering is a common physical vapor deposition method, where atoms or molecules are ejected from a target material by high-energy particle bombardment and then deposited onto the substrate.

The resistivity or density of a thin film deposited on a substrate through a plasma deposition process, such as PVD, may vary between the center and edge regions of the substrate even when the thickness of the film is fairly uniform. This non-uniform resistivity for a conductive film or non-uniform density of a dielectric film is partly due to differences in plasma characteristics between the center and edge of the substrate. Magnetic and electrical field gradients inside the PVD chamber may cause non-uniformity in the ion flux densities at a substrate center and edge. Consequently, the ions of the sputter gas, e.g., argon ions or Ar⁺, and electron bombardment is not uniform across the substrate surface, which in turn leads to issues of non-uniform film density and resistivity across the surface of the substrate.

What is needed is the ability to achieve uniform ion flux densities across the surface of a substrate in order to achieve optimized uniformity with respect to film density, resistivity, uniformity etc. It is within this context that the current embodiments arise.

### SUMMARY

Embodiments of the present invention provide a sputter processing tool and method that optimizes deposited film characteristics through magnetic field distribution. Several inventive embodiments of the present invention are described below.

In one aspect of the invention, a process chamber is provided. The process chamber includes a plurality of sputter guns with a target affixed to one end of each of the sputter guns. Each of the plurality of sputter guns is coupled to a first power source. A substrate support is disposed at a distance from the plurality of sputter guns and the substrate support is coupled to a second power source. A main magnet, or so-called “magnetron”, is disposed behind each of the sputter guns in a magnetron sputtering configuration. In RF sputtering, the magnet behind the target may not necessarily be a closed loop magnetron such as those used for DC magnetron sputtering. An auxiliary magnet is disposed near the substrate. The auxiliary magnet surrounds an outer peripheral surface of the substrate support in some embodiments, wherein a planar top surface of the magnet is below a planar top surface of the substrate support. In alternative embodiments the auxiliary magnet may be disposed in a plate or holder disposed below or above the substrate support. In additional embodiments, the auxiliary magnet may be embedded within the substrate support. Furthermore, the auxiliary magnet can either be permanent magnets or electromagnets.

In another aspect of the invention a method of processing a substrate is provided. The method initiates with depositing a layer of material onto the substrate through a sputtering process. While depositing the layer, the method includes applying a magnetic field proximate to a surface of the substrate. The magnetic field is applied through a magnet disposed near the substrate. The magnet is disposed below a top surface of the substrate, and the magnetic field generated by the magnet is operable to smooth an ion flux density distribution across a diameter of the surface of the substrate.

Other aspects of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings. Like reference numerals designate like structural elements.

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with one embodiment of the invention.

FIG. 3 is a simplified schematic diagram illustrating an integrated high productivity combinatorial (HPC) system in accordance with some embodiments of the invention.

FIG. 4 is a simplified schematic diagram illustrating a processing chamber configured to perform combinatorial processing and full substrate processing in accordance with some embodiments of the invention.

FIGS. 5A and 5B are simplified schematic diagrams illustrating cross-sectional views of a substrate support and an electromagnet coil proximate to the substrate support within the processing chamber in accordance with some embodiments of the invention.

FIGS. 6A and 6B illustrate alternative embodiments for incorporating auxiliary magnets into a process chamber below a surface of a substrate in accordance with some embodiments of the invention.

FIGS. 7A and 7B are simplified schematic diagrams illustrating a top view of the orientation of the auxiliary magnets in accordance with some embodiments of the invention.

FIGS. 8A through 8C illustrate the argon flux density distribution across a substrate and the impact of the auxiliary magnets on the argon flux density in accordance with some embodiments of the invention.

FIG. 9 is a graphical illustration presenting the impact of the auxiliary magnets on the resistivity of a deposited film of titanium nitride (TiN) in accordance with some embodiments of the invention.

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

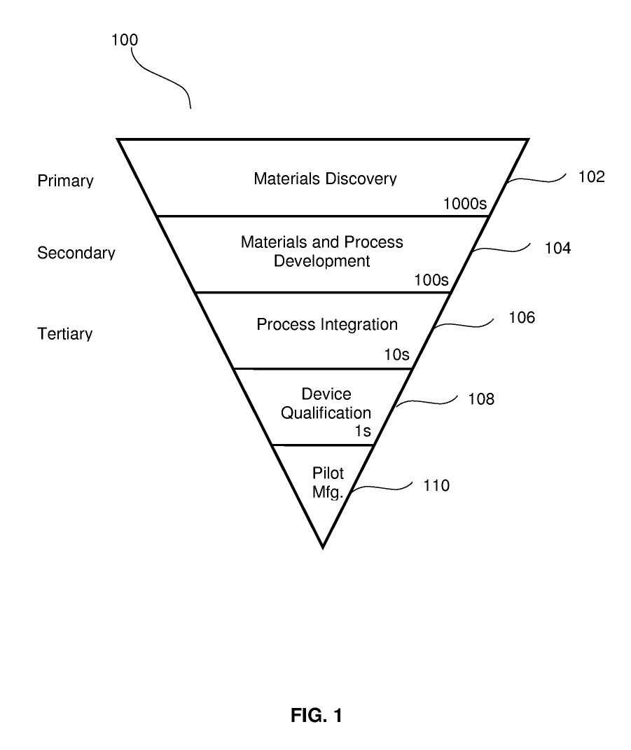

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

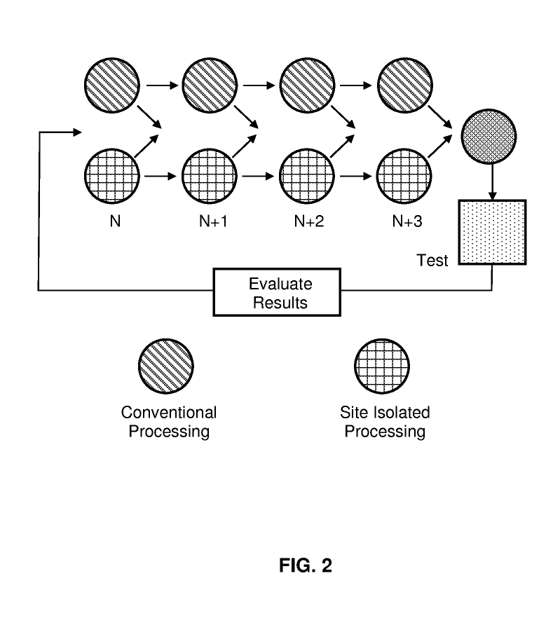

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

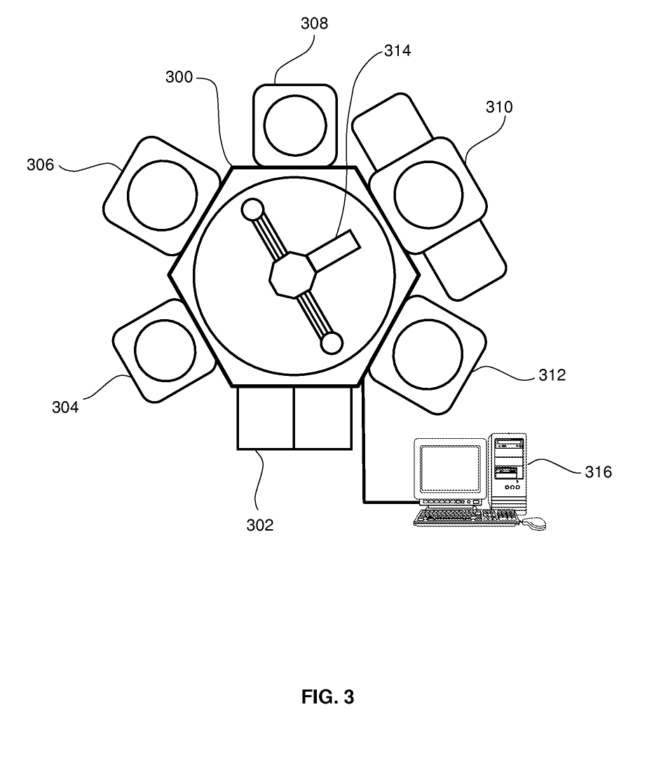

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

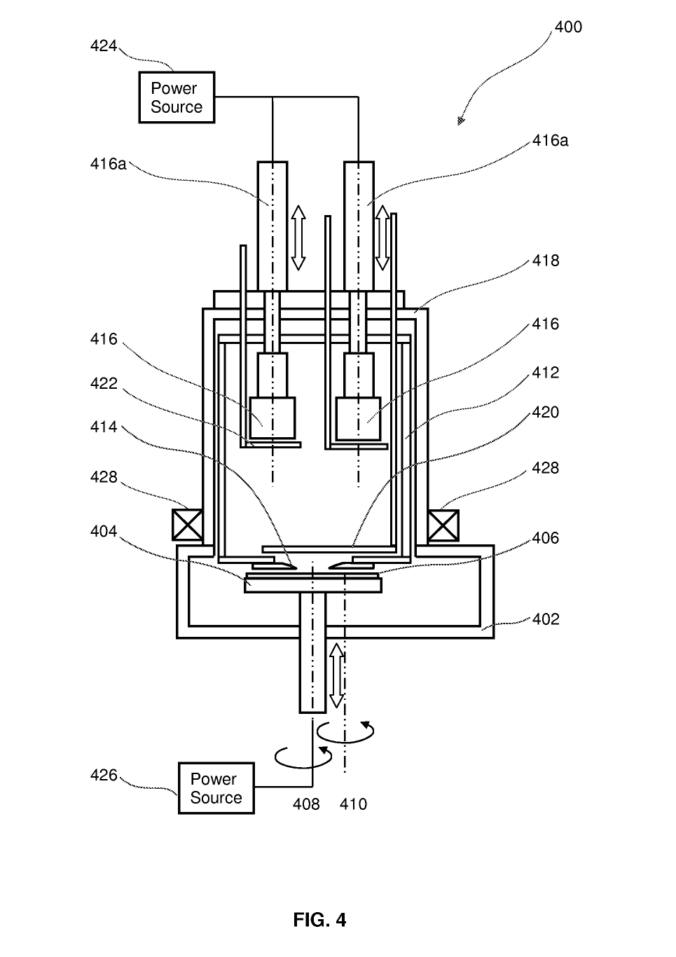

FIG. 4 is a simplified schematic diagram illustrating a sputter chamber configured to perform combinatorial processing and full substrate processing in accordance with some embodiments of the invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In another embodiment, the RF power supplied by power source 426 is pulsed and synchronized with the pulsed power from power source 424. Further details of the power sources and their operation may be found in U.S. patent application Ser. No. ______ entitled “High Metal Ionization Sputter Gun” filed on Oct. xx, 2011 with internal docket number (IMO281) and is herein incorporated by reference.

Substrate 406 may be a conventional round 200 mm, 300 mm, or any other larger or smaller substrate/wafer size. In other embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In another embodiment, substrate 406 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in some embodiments. In another embodiment, full wafer processing can be achieved by optimizing gun tilt angle and target-to-substrate spacing, and by using multiple process guns 416. Process kit shield 412 is capable of being moved in and out of chamber 400, i.e., the process kit shield is a replaceable insert. In another embodiment, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In another embodiment, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

A gun shutter, 422 may be included. Gun shutter 422 functions to seal off a deposition gun when the deposition gun may not be used for the processing in some embodiments. For example, two process guns 416 are illustrated in FIG. 4. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter 422 can be transitioned to isolate the lifted process guns from the processing area defined within process kit shield 412. In this manner, the process guns are isolated from certain processes when desired. It should be appreciated that slide cover plate 422 may be integrated with the top of the process kit shield 412 to cover the opening as the process gun is lifted or individual cover plate 422 can be used for each target. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to process guns 416 may be attached to a suitable drive, e.g., lead screw, worm gear, etc., configured to vertically move process guns 416 toward or away from a top plate of top chamber portion 418. Arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in another embodiment. In yet another embodiment, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments.

Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply.

Chamber 400 includes external magnet 428 disposed around an external periphery of the chamber. In some embodiments, the external magnet 428 is located in a region defined between the bottom surface of sputter guns 416 and a top surface of substrate 406. In some embodiments, the external magnet 428 is located outside the external periphery of the chamber, but at or below the plane defined by the top surface of substrate 406. External magnet 428 may be either a permanent magnet or an electromagnet. It should be appreciated that external magnet 428 is utilized to provide more uniform bombardment of Argon ions and electrons to the substrate in some embodiments.

In some embodiments, auxiliary magnet may be disposed inside the process chamber and proximate to substrate support 404. Alternatively, auxiliary magnet may be integrated within substrate support 104 as described in more detail below. As used herein, magnets not associated with the primary magnetron that are disposed inside the process chamber will be referred to as “auxiliary magnets”.

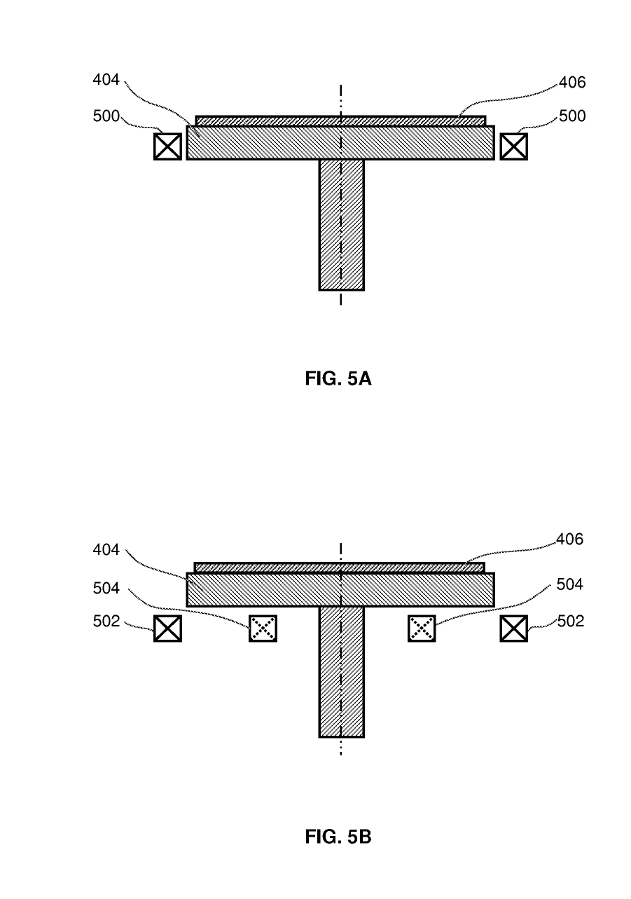

FIGS. 5A and 5B are simplified schematic diagrams illustrating cross-sectional views of a substrate support and an electromagnet coil (i.e. auxiliary magnet) proximate to the substrate support within the processing chamber in accordance with some embodiments of the invention. In FIG. 5A, the electromagnet coil 500 is disposed around a peripheral edge of a substrate support 404. Electromagnet coil 500 may be affixed to the side surface of substrate support 404 and therefore rotate and move along with substrate support 404. Where cooling is necessary for electromagnet coil 500 when coil current is relatively high, the cooling supplied to substrate support 404 may be utilized to cool the electromagnet coil. FIG. 5B illustrates an alternative embodiment to the electromagnet coil location of FIG. 5A. Electromagnet coils 502 and 504 are located below a bottom surface of substrate support 404. It should be appreciated that the current flow direction, clockwise vs. counterclockwise, of electromagnet coils 502 and 504 can either be the same or opposite. Electromagnet coils 502 and 504 may also be individually affixed to a surface of substrate support 404 or to the rotatable shaft of the substrate support. In addition electromagnet coils 502 and 504 may utilize the cooling system associated with substrate support 404. In some embodiments, permanent magnets may be substituted for the electromagnet coils of FIGS. 5A and 5B.

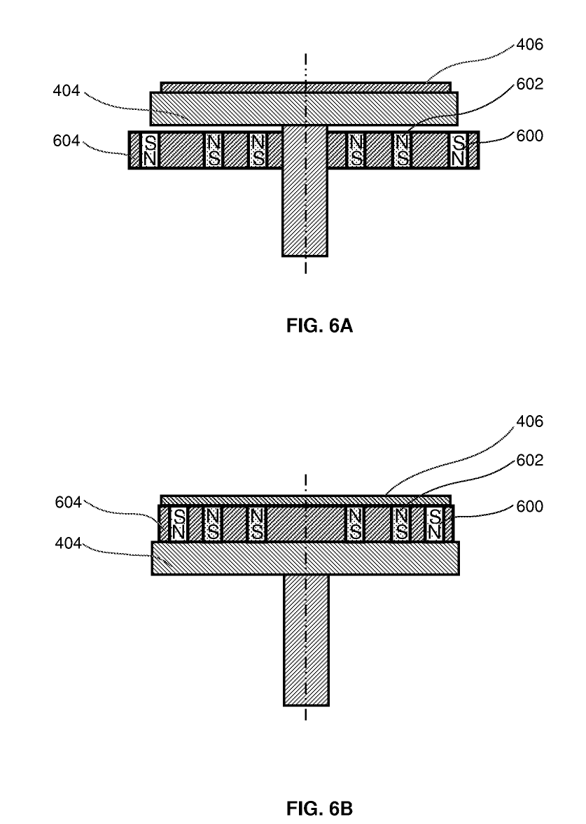

FIGS. 6A and 6B illustrate alternative embodiments for incorporating auxiliary magnets into a process chamber below a surface of a substrate in accordance with some embodiments of the invention. Holder 604 for magnets 600 and 602 is coupled to a shaft of substrate support 404. In one embodiment holder 604 may be coupled to a bottom surface of substrate 404. It should be appreciated that the orientation of magnets 600 and 602 are different. That is, the two inner magnets 602 have their poles oriented differently than the pole of the outer magnet 600. FIG. 6B illustrates holder 604 located on a top surface of substrate support 404. In this embodiment substrate 406 is supported on a top surface of holder 604. Magnets 602 and 600 are disposed within holder 604 as described above with reference to FIG. 6A. In one embodiment holder 604 is affixed to a top surface of substrate support 404. It should be appreciated that magnets 600 and 602 may be electromagnets or permanent magnets. In addition, the orientation of the poles of the magnets is meant to be illustrative as alternative orientations are possible. Holder 604 is composed of any suitable non-ferromagnetic material, such as stainless steel, that is compatible with the processing environment in the chamber.

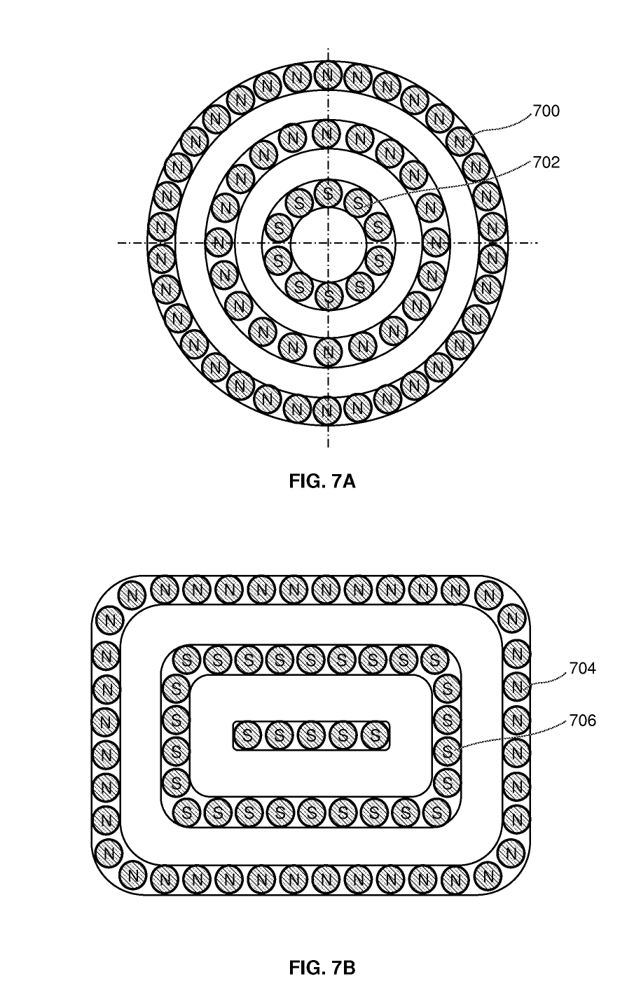

FIGS. 7A and 7B are simplified schematic diagrams illustrating a top view of the orientation of auxiliary magnets in accordance with some embodiments of the invention. In FIG. 7A concentric rings of magnets are illustrated. Inner ring 702 is surrounded by middle and outer rings 700. It should be appreciated that inner ring 702 has a different orientation with regard to the poles relative to the middle ring and outer ring 700. In some embodiments, the magnets illustrated in FIGS. 7A and 7B are disposed in holder 604 of FIGS. 6A and 6B. FIG. 7B illustrates a configuration suitable for a rectangular substrate and may be referred to as a racetrack configuration. In FIG. 7B, a centrally located strip of magnets is surrounded by middle section of magnets 706 and outer section of magnets 704. It should be appreciated that numerous geometric configurations of the magnets are possible and FIGS. 7A and 7B are meant to be illustrative and not limiting. In addition, the magnets may be integrated into the substrate support in other embodiments. Where the magnets are permanent magnets inside the chamber one skilled in the art will appreciate that the processing temperature in the chamber will typically be less than 300° C., or active cooling of auxiliary magnets will be required to prevent demagnetization at elevated temperatures.

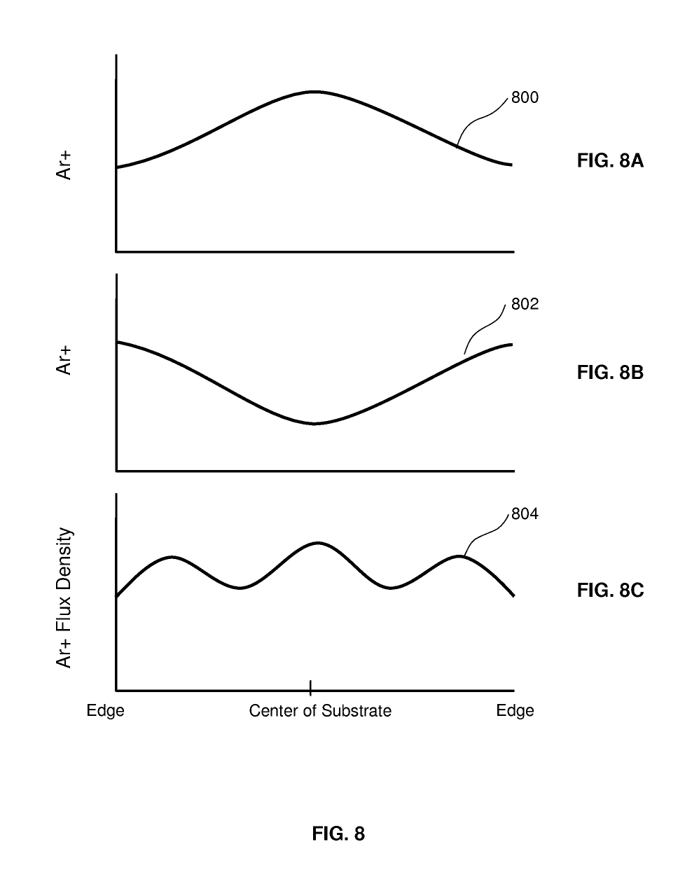

FIGS. 8A through 8C illustrate the argon flux density distributions across a substrate and the impact of the auxiliary magnets on the argon flux density distribution in accordance with some embodiments of the invention. In FIG. 8A the argon flux density is somewhat focused on the center of the substrate, while FIG. 8B illustrates the argon flux density more focused on the outer periphery of the substrate. Utilization of the auxiliary magnets illustrated in FIGS. 5A through 7B have a smoothing effect that modulates the argon flux density so that there is less of a variation between the edge and center of the substrate with respect to the argon flux density. That is, the range of the argon flux density in FIG. 8C varies over a smaller range compared to the range of the argon flux density between the center of the substrate and the edge of the substrate in FIGS. 8A and 8B, as the embodiments flatten out the ion flux distribution over the surface of the substrate.

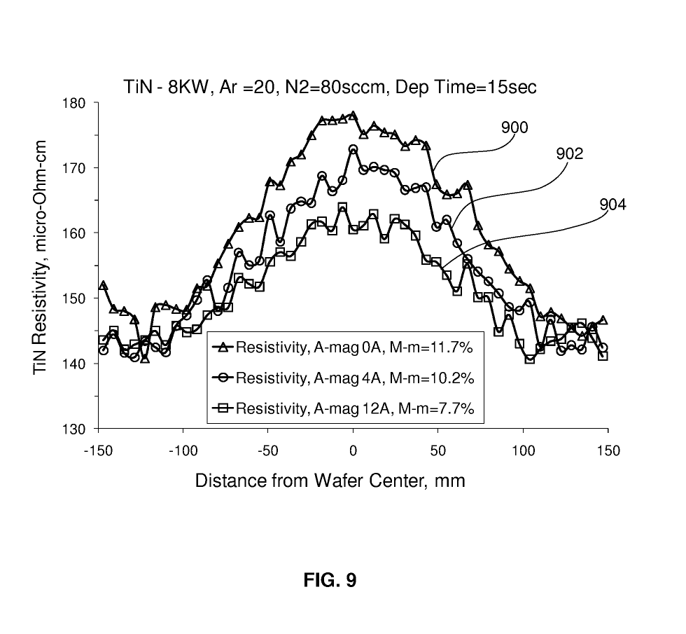

FIG. 9 is a graphical illustration presenting the impact of the auxiliary magnets on the resistivity of a deposited film of titanium nitride (TiN) in accordance with one embodiment of the invention. Plots 900, 902, and 904 illustrate the resistivity of the TiN film at various locations along the substrate surface. Plot 900 illustrates the resistivity of a film deposited without any current flowing through a substrate level electromagnet coil. Plot 902 illustrates the resistivity across the surface of the substrate of the deposited film when the substrate level electromagnet coil has a current of 4 amperes (A) flowing therethrough. Plot 904 illustrates the resistivity across the surface of the substrate of the deposited film when the electromagnet is powered with 12 A. As illustrated in FIG. 9 the application of the auxiliary electromagnet proximate to the substrate level as described above improves the uniformity of the film resistivity. That is, the range of the resistivity, “measured as max-min” from the center to the edge of the substrate is reduced from 11.7% to 7.7%.

The present invention provides greatly improved methods and apparatus for the combinatorial processing of different regions on a single substrate and processing of full substrate. It is to be understood that the above description is intended to be illustrative and not restrictive. Many embodiments and variations of the invention will become apparent to those of skill in the art upon review of this disclosure. Merely by way of example a wide variety of process times, process temperatures and other process conditions may be utilized, as well as a different ordering of certain processing steps. The scope of the invention should, therefore, be determined not with reference to the above description, but instead should be determined with reference to the appended claims along with the full scope of equivalents to which such claims are entitled.

The embodiments described above provide methods and apparatus for the parallel or rapid serial synthesis, processing and analysis of novel materials having useful properties identified for semiconductor manufacturing processes. Any materials found to possess useful properties can then subsequently be prepared on a larger scale and evaluated in actual processing conditions. These materials can be evaluated along with reaction or processing parameters through the methods described above. In turn, the feedback from the varying of the parameters provides for process optimization. Some reaction parameters which can be varied include, but are not limited to, process material amounts, reactant species, processing temperatures, processing times, processing pressures, processing gas flow rates, processing powers, processing reagent compositions, the rates at which the reactions are quenched, atmospheres in which the processes are conducted, an order in which materials are deposited, etc. In addition, the methods described above enable the processing and testing of more than one material, more than one processing condition, more than one sequence of processing conditions, more than one process sequence integration flow, and combinations thereof, on a single substrate without the need of consuming multiple substrates per material, processing condition, sequence of operations and processes or any of the combinations thereof. This greatly improves the speed as well as reduces the costs associated with the discovery and optimization of semiconductor and other manufacturing operations.

Moreover, the embodiments described herein are directed towards delivering precise amounts of material under precise processing conditions at specific locations of a substrate in order to simulate conventional manufacturing processing operations. As mentioned above, within a region the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes and process sequences may vary. It should be noted that the discrete steps of uniform processing is enabled through the HPC systems described herein.

Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A process chamber, comprising:
a plurality of sputter guns with a target affixed to one end of each of the sputter guns, each of the plurality of sputter guns coupled to a first power source;
a substrate support disposed below the plurality of sputter guns, the substrate support coupled to a second power source; and
an auxiliary magnet within an internal region of the process chamber, the auxiliary magnet proximate to the substrate support, wherein a planar top surface of the auxiliary magnet is below a planar top surface of the substrate support.

2. The chamber of claim 1, wherein the auxiliary magnet is an electromagnet.

3. The chamber of claim 1, wherein the auxiliary magnet is a permanent magnet.

4. The chamber of claim 1 wherein the auxiliary magnet is affixed to the outer peripheral surface of the substrate support.

5. The chamber of claim 1, wherein the auxiliary magnet is cooled through a cooling system.

6. The chamber of claim 1, further comprising;
an external electromagnet disposed around an outer peripheral surface of the chamber, the external electromagnet located in a plane defined between a bottom surface of the plurality of sputter guns and a top surface of the substrate support.

7. The chamber of claim 1, wherein the auxiliary magnet is disposed below the substrate support.

8. The chamber of claim 1, wherein the auxiliary magnet is integrated into a plate disposed below the substrate support.

9. The chamber of claim 8, wherein the plate includes a first auxiliary magnet, a second auxiliary magnet, and a third auxiliary magnet configured as concentric rings extending through the plate.

10. The chamber of claim 9, wherein poles of the first auxiliary magnet and the second auxiliary magnet are oriented differently than a pole of the third auxiliary magnet.

11. The chamber of claim 1, wherein the substrate support is rotatable.

12. The chamber of claim 1, wherein the auxiliary magnet is disposed above the substrate support and below the substrate.

13. The chamber of claim 12, wherein the auxiliary magnet is integrated into a plate disposed above the substrate support and below the substrate.

14. A method of processing a substrate, comprising;
depositing a layer of material onto the substrate through a sputtering process; and
while depositing the layer, applying a magnetic field proximate to a surface of the substrate, the magnetic field applied through an auxiliary magnet proximate to the substrate, the auxiliary magnet disposed below a top surface of the substrate, and wherein the magnetic field is operable to smooth an ion flux density distribution across the surface of the substrate.

15. The method of claim 14, further comprising:
cooling the auxiliary magnet with a fluid distributed from a cooling system.

16. The method of claim 14, further comprising:
rotating the substrate while depositing the layer.

17. The method of claim 14, wherein the magnetic field is applied through a permanent magnet.

18. The method of claim 14, wherein the magnetic field is applied through a electromagnet.

19. The method of claim 14, wherein the auxiliary magnet is disposed within the chamber.
